(19) United States
(12) Patent Application Publication
(10) Pub. No.: US 2012/0137973 A1
(43) Pub. Date: Jun. 7, 2012

(54) SUBSTRATE PROCESSING APPARATUS AND FILM FORMING SYSTEM

(75) Inventor: Nobuyoshi SATO, Mie (JP)

(73) Assignee: Kabushiki Kaisha Toshiba, Tokyo (JP)

(21) Appl. No.: 13/238,185

(22) Filed: Sep. 21, 2011

(30) Foreign Application Priority Data
Dec. 6, 2010 (JP) 2010-271256
Sep. 2, 2011 (JP) 2011-191498

(51) Int. Cl. C23C 16/02; C23C 16/46

(52) U.S. Cl. 118/719

(57) ABSTRACT

According to one embodiment, there is provided a substrate processing apparatus which performs a preprocess of a substrate to which a film forming process is performed by a CVD device. The substrate processing apparatus comprises a substrate process chamber, a heating unit, an oxidation process unit, and a coating process unit. In the substrate process chamber, a substrate stage is disposed. The substrate stage holds the substrate. The heating unit heats the substrate in the substrate process chamber via the substrate stage. The oxidation process unit oxidizes a surface of the substrate heated by the heating unit in the substrate process chamber. The coating process unit coats the surface of the substrate oxidized by the oxidation process unit with an organic solvent in the substrate process chamber.

### CROSS-REFERENCE TO RELATED APPLICATIONS

This application is based upon and claims the benefit of priority from Japanese Patent Application No. 2010-271256, filed on Dec. 6, 2010 and Japanese Patent Application No. 2011-191498, filed on Sep. 2, 2011; the entire contents of which are incorporated herein by reference.

### FIELD

Embodiments described herein relate generally to a substrate processing apparatus and a film forming system.

### BACKGROUND

Recently, to respond to a requirement for increasing the capacity of and reducing the cost of a semiconductor device, miniaturization of an element is accelerated. As the element is miniaturized, the width of an STI type element isolation region, which is to be formed by forming a groove or a hole (hereinafter, called a groove and the like) to a semiconductor substrate and burying an insulator in the groove and the like by a CVD device, becomes also thin. Further, as the element is miniaturized, the width of a predetermined structure, which is to be formed by forming a groove and the like to a predetermined film and burying an insulator in the groove and the like by a CVD device, becomes also thin. As described above, when the aspect ratio of the groove and the like in which the insulator is buried becomes high, it is concerned that the gap-fill capability of the insulator in the groove and the like by the CVD device becomes insufficient. When the gap-fill capability of the insulator in the groove and the like by the CVD device becomes insufficient, there is a possibility that the reliability of a semiconductor device manufactured by the CVD device is deteriorated. Accordingly, it is desired to develop an apparatus for performing a preprocess for improving the gap-fill capability of an insulator in a groove and the like by a CVD device.

### BRIEF DESCRIPTION OF THE DRAWINGS

FIG. 1 is a view illustrating a configuration of a film forming system according to a first embodiment;

FIG. 2 is a view illustrating an operation of the film forming system according to the first embodiment;

FIGS. 3A to 3D are views illustrating a manufacturing method of a semiconductor device by the film forming system according to the first embodiment;

FIG. 4 is a view illustrating a manufacturing method of a semiconductor device by a film forming system according to a modification of the first embodiment;

FIG. 5 is a view illustrating a configuration of a film forming system according to another modification of the first embodiment;

FIG. 6 is a view illustrating a configuration of a film forming system according to still another modification of the first embodiment;

FIG. 7 is a view illustrating a configuration of a film forming system according to a second embodiment; and

FIGS. 8A to 8D are views illustrating a configuration of a spray nozzle in the second embodiment.

### DETAILED DESCRIPTION

In general, according to one embodiment, there is provided a substrate processing apparatus which performs a preprocess of a substrate to which a film forming process is performed by a CVD device. The substrate processing apparatus comprises a substrate process chamber, a heating unit, an oxidation process unit, and a coating process unit. In the substrate process chamber, a substrate stage is disposed. The substrate stage holds the substrate. The heating unit heats the substrate in the substrate process chamber via the substrate stage. The oxidation process unit oxidizes a surface of the substrate heated by the heating unit in the substrate process chamber. The coating process unit coats the surface of the substrate oxidized by the oxidation process unit with an organic solvent in the substrate process chamber.

Exemplary embodiments of a substrate processing apparatus and a film forming system will be explained below in detail with reference to the accompanying drawings. The present invention is not limited to the following embodiments.

### FIRST EMBODIMENT

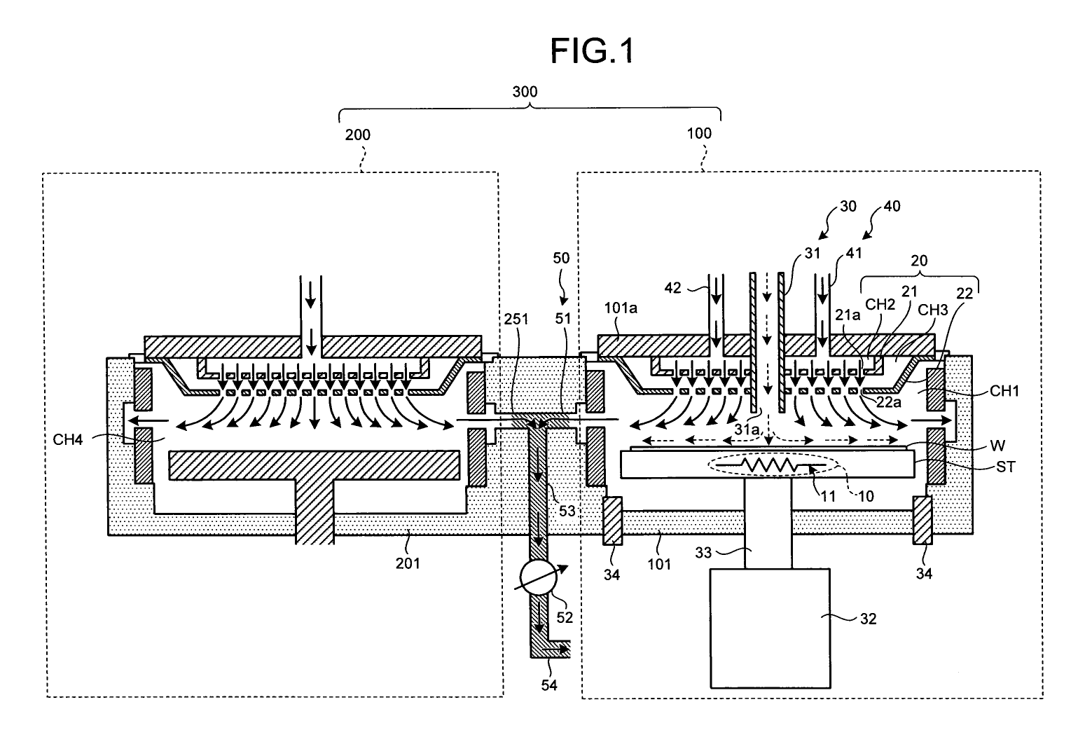

A configuration of a film forming system 300 according to a first embodiment will be explained using FIG. 1. FIG. 1 is a sectional view illustrating a configuration of the film forming system 300.

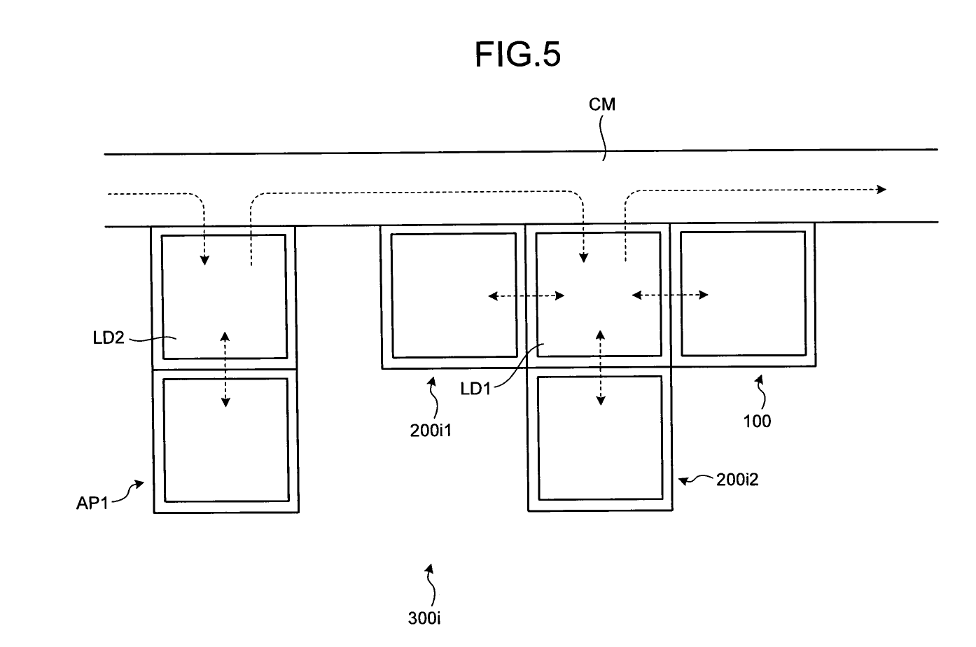

The film forming system 300 includes a substrate processing apparatus 100, a load lock chamber LD1 (refer to FIG. 5), and a CVD device 200.

The substrate processing apparatus 100 is an apparatus for performing a preprocess of a substrate W to be subjected to a film forming process by the CVD device 200. That is, the substrate W has a groove or a hole (hereinafter, called a groove and the like) on a surface in which an insulator is to be buried by the CVD device 200. The substrate processing apparatus 100 performs the preprocess to improve the gap-fill capability of an insulator in the groove and the like by the CVD device 200.

The substrate processing apparatus 100 is disposed adjacent to, for example, the CVD device 200. At the time, an outside wall 101 of the substrate processing apparatus 100 may be integrated with an outside wall 201 of the CVD device 200. Further, a part of a pressure control unit 50 (51, 53, 52) of a substrate process chamber CH1 in the substrate processing apparatus 100 may be commonly used by pressure control units (251, 53, 52) of a substrate process chamber CH4 in the CVD device 200. FIG. 1 illustrates a configuration example in which an exhaust pipe 53 and a pressure controller 52 are commonly used by the substrate processing apparatus 100 and the CVD device 200. The exhaust pipe 53 is connected to an exhaust pipe 51 extending from the substrate process chamber CH1 and to an exhaust pipe 251 extending from the substrate process chamber CH4. The pressure controller 52 adjusts the pressure of the substrate process chamber CH1 and the pressure of the substrate process chamber CH4 to a substantially the same pressure.

The load lock chamber LD1 (refer to FIG. 5) is disposed adjacent to, for example, the substrate processing apparatus 100 and the CVD device 200. The load lock chamber LD1 supports to transport the substrate W from the substrate processing apparatus 100 to the CVD device 200 without exposing the substrate W to the atmosphere. Specifically, the substrate W, which is subjected to the preprocess by the substrate processing apparatus 100, is carried into the load lock chamber LD1 from the substrate process chamber CH1 of the substrate processing apparatus 100. Thereafter, the substrate W is carried out of the load lock chamber LD1 into the substrate process chamber CH4 of the CVD device 200.

Note that when the pressure control units (51, 53, 52) of the substrate process chamber CH1 in the substrate processing apparatus 100 are not commonly used by the pressure control units (251, 53, 52) of the substrate process chamber CH4 in the CVD device 200 and the pressure of the substrate process chamber CH1 and the pressure of the substrate process chamber CH4 are adjusted to a different pressure, the load lock chamber LD1 is preferably disposed with a pressure control unit (not illustrated). That is, after the substrate W is carried in, the pressure control unit adjusts the pressure of the load lock chamber LD1 so that the pressure becomes substantially the same as the pressure of the substrate process chamber CH4. With the operation, the substrate W is carried out into the substrate process chamber CH4 in a state that the pressure of the load lock chamber LD1 becomes substantially the same as the pressure of the substrate process chamber CH4.

The CVD device 200 subjects the substrate W, which is subjected to the preprocess by the substrate processing apparatus 100 in the substrate process chamber CH4, to a film forming process of an insulator. A predetermined insulation film is an ozone TEOS film. Note that the CVD device 200 may perform the film forming process by APCVD (normal pressures CVD), may perform the film forming process by SACVD (quasi-normal pressures CVD), may perform the film forming process by LPCVD (pressure reduction CVD), may perform the film forming process by pressure increase CVD, or may perform the film forming process by plasma CVD. When the CVD device 200 performs the film forming process by APCVD, the pressure controller 52 adjusts the pressure of the substrate process chamber CH4 to substantially the atmospheric pressure. When the CVD device 200 performs the film forming process by SACVD, the pressure controller 52 adjusts the pressure of the substrate process chamber CH4 to a pressure value slightly reduced from the atmospheric pressure. When the CVD device 200 performs the film forming process by LPCVD, the pressure controller 52 adjusts the pressure of the substrate process chamber CH4 to a pressure value reduced from the atmospheric pressure. When the CVD device 200 performs the film forming process by pressure increase CVD, the pressure controller 52 adjusts the pressure of the substrate process chamber CH4 to a pressure value increased from the atmospheric pressure. When the CVD device 200 performs the film forming process by plasma CVD, the pressure controller 52 adjusts the pressure of the substrate process chamber CH4 to a pressure value suitable to generate plasma.

Next, a detailed configuration of the substrate processing apparatus 100 will be explained using FIG. 1.

The substrate processing apparatus 100 includes the substrate process chamber CH1, a heating unit 10, an oxidation process unit 20, a coating process unit 30, a gas supply unit 40, and a pressure control unit 50.

In the substrate process chamber CH1, a substrate stage ST is disposed. The substrate stage ST holds the substrate W so as to cover it from a back surface side. The substrate stage ST includes, for example, a vacuum chuck and may hold the substrate W so as to adsorb it by vacuum from the back surface side using the vacuum chuck. Otherwise, the substrate stage ST includes, for example, an electrostatic chuck and may hold the substrate W so as to electrostatically adsorb it from the back surface side using the electrostatic chuck.

The heating unit 10 heats the substrate W in the substrate process chamber CH1 via the substrate stage ST. Specifically, the heating unit 10 includes a heater 11. The heater 11 is disposed inside the substrate stage ST so as to heat the substrate W via the substrate stage ST. The heater 11 is formed of a material heated by resistance thereof and formed of, for example, nickel chromium alloy.

The oxidation process unit 20 oxidizes a surface of the substrate W in the substrate process chamber CH1. Specifically, the oxidation process unit 20 includes a gas introducing chamber CH2, a diffusion plate 21, a diffusion chamber CH3, and a shower plate 22.

The gas introducing chamber CH2 is formed by being surrounded by an upper portion 101a of the outside wall 101 and the diffusion plate 21. The gas introducing chamber CH2 is introduced with an oxidizing gas via the gas supply unit 40. The oxidizing gas is a gas containing at least one of, for example, oxygen and ozone.

The diffusion plate 21 separates the gas introducing chamber CH2 from the diffusion chamber CH3 as well as isolates the gas introducing chamber CH2 from the substrate process chamber CH1. The diffusion plate 21 has plural through holes 21a for communicating the gas introducing chamber CH2 with the substrate process chamber CH1 via the diffusion chamber CH3.

The diffusion chamber CH3 is formed by being surrounded by the diffusion plate 21 and the shower plate 22. The diffusion chamber CH3 is interposed between the gas introducing chamber CH2 and the substrate process chamber CH1 via the diffusion plate 21 and the shower plate 22. As illustrated by solid arrows in FIG. 1, the diffusion chamber CH3 is supplied with the oxidizing gas from the gas introducing chamber CH2 via plural through holes 21a of the diffusion plate 21.

The shower plate 22 separates the diffusion chamber CH3 from the substrate process chamber CH1 as well as isolates the gas introducing chamber CH2 from the substrate process chamber CH1. The shower plate 22 has plural through holes 22a for communicating the gas introducing chamber CH2 with the substrate process chamber CH1 via the diffusion chamber CH3. As illustrated by the solid arrows in FIG. 1, the substrate process chamber CH1 is supplied with the oxidizing gas from the diffusion chamber CH3 via the plural through holes 22a of the shower plate 22.

That is, the oxidation process unit 20 supplies the oxidizing gas onto the surface of the substrate W in the substrate process chamber CH1 from the gas introducing chamber CH2 via the plural through holes 21a, the diffusion chamber CH3, and the plural through holes 22a.

Note that the oxidation process unit 20 may perform plasma oxidation by causing at least one of the gas introducing chamber CH2 and the diffusion chamber CH3 to generate plasma. When the gas introducing chamber CH2 is caused to generate plasma, the upper portion 101a of the outside wall 101 is connected to a high-frequency power supply (not illustrated). When the diffusion chamber CH3 is caused to generate plasma, the diffusion plate 21 is connected to the high-frequency power supply (not illustrated). With the configuration, since active species of a radical, a positive ion, or a negative ion in the plasma of the oxidizing gas can be introduced onto the surface of the substrate W, the surface of the substrate W can be oxidized at high speed.

The coating process unit 30 coats the surface of the substrate W in the substrate process chamber CH1 with an organic solvent. Specifically, the coating process unit 30 includes a rotation unit 32 and a nozzle 31.

The rotation unit 32 is connected to the substrate stage ST via a shaft 33. With the configuration, the rotation unit 32 rotates the substrate stage ST via the shaft 33.

The nozzle 31 is connected to a chemical tank (not illustrated) via a predetermined pipe and a predetermined on-off valve and is supplied with the organic solvent stored in the chemical tank. The nozzle 31 is disposed above the substrate stage ST and has an ejection port 31a facing a central portion of the substrate stage ST. With the configuration, as illustrated by broken arrows in FIG. 1, the nozzle 31 supplies the organic solvent onto the surface of the substrate W held by the substrate stage ST. The organic solvent contains organic molecules in which, for example, a hydroxy group (—OH) is coupled with an alkyl group (R). Further, the organic solvent may be a mixed solvent of plural organic solvents.

Note that the coating process unit 30 may further include an exhaust mechanism 34 for exhausting a space in the vicinity of the outer periphery of the substrate stage ST downward. With the configuration, a volatile component evaporated from the organic solvent can be easily exhausted so that drying and fixing of the organic solvent coated on the surface of the substrate W can be accelerated.

Further, a predetermined flow rate adjusting unit may be interposed between the chemical tank and the nozzle 31. The flow rate adjusting unit may adjust the amount of the organic solvent supplied onto the surface of the substrate W in response to the rotation speed of the substrate stage ST rotated by the rotation unit 32.

The gas supply unit 40 includes gas supply pipes 41, 42 and is connected to a gas supply source (not illustrated) via the gas supply pipes 41, 42, a predetermined pipe and a predetermined on-off valve, and the oxidizing gas is supplied from the gas supply source to the gas supply pipes 41, 42. The gas supply pipes 41, 42 are caused to communicate with the gas introducing chamber CH2. With the configuration, as illustrated by the broken arrows in FIG. 1, the gas supply unit 40 supplies the oxidizing gas into the gas introducing chamber CH2 via the gas supply pipes 41, 42.

Note that when the gas supply unit 40 supplies an ozone gas or a mixed gas of ozone and oxygen as the oxidizing gas, an ozone generator may be interposed between the gas supply pipes 41, 42 and the gas supply source. The ozone generator changes at least a part of, for example, an oxygen gas supplied from the gas supply source to ozone by radiating ultraviolet rays to the oxygen gas or causing the oxygen gas to be subjected to a silent discharge and supplies the ozone to the gas supply pipes 41, 42.

The pressure control unit 50 controls the pressure of the substrate process chamber CH1 and the exhaust amount of a process gas. Specifically, the pressure control unit 50 includes exhaust pipes 51, 53, 54, a pressure sensor (not illustrated), a pressure controller 52, and a vacuum pump (not illustrated). The pressure sensor detects the pressure in the substrate process chamber CH1 and supplies the information of the value of the pressure to the pressure controller 52. The pressure controller 52 is connected to the substrate process chamber CH1 via the exhaust pipes 51, 53 as well as connected to the vacuum pump via the exhaust pipe 54. The pressure controller 52 includes an adjusting valve capable of adjusting a degree of opening and controls the degree of opening of the adjusting valve in response to the value of the pressure supplied from the pressure sensor so that the pressure in the substrate process chamber CH1 becomes a target value. With the configuration, the pressure of the substrate process chamber CH1 and the exhaust amount of the process gas are controlled.

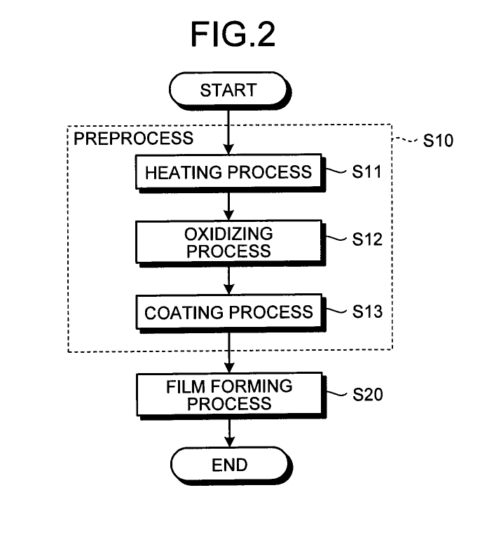

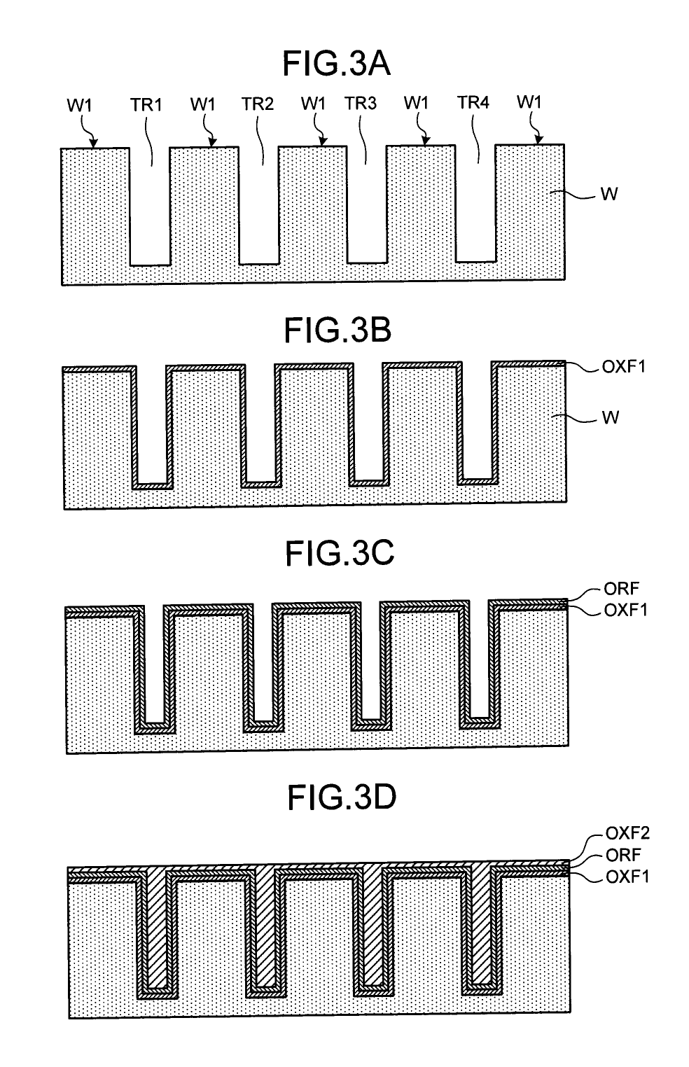

Next, an operation of the film forming system 300 will be explained using FIG. 2 and FIG. 3. FIG. 2 is a flowchart illustrating the operation of the film forming system 300. FIG. 3 is a view illustrating a manufacturing method of a semiconductor device by the film forming system 300.

At step S10, a carrying mechanism CM (refer to FIG. 5) carries the substrate W into the substrate processing apparatus 100. The substrate W has grooves and the like (grooves TR1-TR4 illustrated in, for example, FIG. 3A), in which an insulator is to be buried by the CVD device 200, on the surface. The substrate processing apparatus 100 performs the preprocess of the substrate W which is to be subjected to the film forming process by the CVD device 200. Specifically, the substrate processing apparatus 100 performs the processes of the following steps S11-S13.

At step S11, the heating unit 10 of the substrate processing apparatus 100 heats the substrate W in the substrate process chamber CH1 via the substrate stage ST. That is, the heater 11 disposed inside the substrate stage ST heats the substrate W via the substrate stage ST. With the operation, the heating unit 10 removes moisture on the surface of the substrate W.

At step S12, the oxidation process unit 20 of the substrate processing apparatus 100 oxidizes the surface of the substrate W in the substrate process chamber CH1. That is, the oxidation process unit 20 supplies the oxidizing gas from the gas introducing chamber CH2 onto the surface of the substrate W in the substrate process chamber CH1 via the plural through holes 21a, the diffusion chamber CH3, and the plural through holes 22a. With the operation, the surface of the substrate W is oxidized and, for example, SiOH is formed on the surface of the substrate W. As illustrated in, for example, FIG. 3B, an oxide film OXF1 mainly composed of, for example, SiOH is formed so as to cover surfaces W1 of the substrate W and side surfaces and bottom surfaces of the grooves TR1-TR4 (refer to FIG. 3A).

At step S13, the coating process unit 30 of the substrate processing apparatus 100 rotation-coats the surface of the substrate W in the substrate process chamber CH1 with the organic solvent. That is, the rotation unit 32 rotates the substrate stage ST and, in the state, the nozzle 31 drops the organic solvent onto the surface of the substrate W held by the substrate stage ST as illustrated by the broken arrows in FIG. 1. The dropped organic solvent spreads to the peripheral side of the substrate W by a centrifugal force according to rotation and the surface of the substrate W is coated with the organic solvent. The organic solvent contains plural organic molecules (ROH) in which, for example, a hydroxy group (—OH) is coupled with an alkyl group (R). Otherwise, the organic solvent contains plural organic molecules (ROH) in which, for example, a hydroxy group (—OH) is coupled with an alkyl fluoride group (R). With the operation, the following reaction is performed on the surface of the substrate W.

SiOH+ROH→SiOR+H₂O (1)

That is, SiOR is formed on the entire surface of the substrate W. As illustrated in, for example, FIG. 3C, an organic film ORF mainly composed of, for example, SiOR is formed so as to further cover the surfaces W1 and the side surfaces and the bottom surfaces of the grooves TR1-TR4 of the substrate W covered with the oxide film OXF1 (refer to FIG. 3A).

At step S20, the substrate W which is subjected to the preprocess by the substrate processing apparatus 100 is carried into the load lock chamber LD1 (refer to FIG. 5) from the substrate process chamber CH1 of the substrate processing apparatus 100. Thereafter, the substrate W is carried out from the load lock chamber LD1 into the substrate process chamber CH4 of the CVD device 200.

The CVD device 200 performs the film forming process of the insulator to the substrate W, which is subjected to the preprocess by the substrate processing apparatus 100, in the substrate process chamber CH4. A predetermined insulation film is an ozone TEOS film. At the time, since the surface of the substrate W is reformed, the insulator can be easily buried in the grooves and the like on the surface of the substrate W. As illustrated in, for example, FIG. 3D, an oxide film OXF2 mainly composed of, for example, TEOS is easily formed so as to be buried in the grooves TR1-TR4 of the substrate W covered with the organic film ORF (refer to FIG. 3A).

A case where the substrate processing apparatus 100 is not provided with the heating unit 10 will be tentatively examined here. In the case, the substrate processing apparatus 100 drops the organic solvent onto the surface of the substrate W in a state that moisture remains on the surface of the substrate W. As a result, when the organic solvent has a hydrophobic property, since the organic solvent is less fixed on the surface of the substrate W by the moisture remaining on the surface of the substrate W, it becomes difficult to coat the surface of the substrate W with the organic solvent. Otherwise, even if the organic solvent has a certain degree of a hydrophilic property, when the degree of solubility of the organic solvent to water is limited (for example, when the organic solvent is alcohol having a carbon number of four or more) since the organic solvent is less fixed on the surface of the substrate W by the moisture remaining on the surface of the substrate W, it becomes difficult to coat the surface of the substrate W with the organic solvent. Otherwise, even if the organic solvent has a hydrophilic property and the degree of solubility of the organic solvent is substantially unlimited (for example, when the organic solvent is lower alcohol), when a component which prevents fixing of the organic solvent (impurities such as serine and the like having an alcohol-phobic property and a hydrophilic property) remain on the surface of the substrate W together with moisture, since the component prevents the organic solvent from being fixed on the surface of the substrate W, it becomes difficult to coat the surface of the substrate W with the organic solvent.

Further, a case where the substrate processing apparatus 100 is not provided with the oxidation process unit 20 will be tentatively examined here. In the case, even if the moisture (and the impurities) on the surface of the substrate W can be removed and the surface of the substrate W can be placed in a state that the organic solvent can be easily fixed thereon, since, for example, SiOH is not formed on the surface of the substrate W, even if the organic solvent is dropped onto the surface of the substrate W, the organic solvent cannot be chemically absorbed (otherwise, cannot be combined via a chemical reaction) and thus there is a tendency that the surface of the substrate W cannot be reformed.

In contrast, in the first embodiment, the heating unit 10 heats the substrate W so as to remove moisture on the surface of the substrate W. With the configuration, the surface of the substrate W can be placed in the state where the organic solvent is easily fixed. Then, the oxidation process unit 20 oxidizes the surface of the substrate W from which the moisture is removed by the heating unit 10. With the operation, for example, SiOH is formed on the surface of the substrate W. Although SiOH itself is not a material for improving a gap-fill capability of the insulator buried in the grooves and the like by the CVD device 200, the coating process unit 30 further coats the surface of the substrate W oxidized by the oxidation process unit 20 with the organic solvent. With the operation, the gap-fill capability of the insulator buried in the grooves and the like by the CVD device 200 can be improved. That is, when the film forming process of the insulator is performed by the CVD device 200 thereafter, since the surface of the substrate W is entirely reformed, the insulator can be easily buried in the grooves and the like on the surface of the substrate W.

Accordingly, even if the width of a STI type element isolation region to be formed becomes thin, the insulator can be easily buried in the grooves and the like corresponding to the element isolation region. Further, even if the width of a predetermined structure to be formed becomes thin, the insulator can be easily buried in the grooves and the like corresponding to the predetermined structure. That is, even if the aspect ratio of the grooves and the like in which the insulator is buried becomes high, the deterioration of the gap-fill capability of the insulator buried in the grooves and the like by the CVD device can be suppressed, thereby the reliability of a semiconductor device manufactured by the CVD device can be improved.

A case where the heating unit 10, the oxidation process unit 20, and the coating process unit 30 are disposed inside process chambers of different devices will be tentatively examined. In the case, after the completion of the heating process performed by the heating unit 10, the substrate W subjected to the heating process is transported from a device for the heating unit 10 to a device for the oxidation process unit 20 via a predetermined load lock chamber. After the completion of the oxidation process performed by the oxidation process unit 20, the substrate W subjected to the oxidation process is transported from the device for the oxidation process unit 20 to the device for the coating process unit 30 via a predetermined load lock chamber. As described above, since transport via the load lock chamber is necessary each time one process is finished, there is a tendency that a time necessary for the preprocess increases and the throughput of the preprocess is deteriorated. Further, it is contemplated that moisture and the like are adsorbed in a transport path during a waiting time, and there is a possibility that the reform of the substrate surface is prevented.

In contrast, in the first embodiment, the heating unit 10, the oxidation process unit 20, and the coating process unit 30 perform respective processes in the substrate process chamber CH1 which is the same process chamber. With the operation, since transport is not necessary while the preprocess is being performed, a process time necessary to the preprocess can be reduced and the throughput of the preprocess can be improved as well as the substrate surface can be effectively reformed.

Further, in the first embodiment, the coating process unit 30 includes the rotation unit 32 for rotating the substrate stage ST and the nozzle 31 disposed above the substrate stage ST so as to supply the organic solvent onto the surface of the substrate W. With the configuration, the coating process unit 30 can be realized by a simple configuration.

Further, in the first embodiment, the oxidation process unit 20 includes the gas introducing chamber CH2 into which the oxidizing gas is introduced and the shower plate 22 which isolates the gas introducing chamber CH2 from the substrate process chamber CH1 as well as has the plural through holes 22a for communicating the gas introducing chamber CH2 with the substrate process chamber CH1. With the configuration, the oxidation process unit 20 can be realized by a simple configuration.

Further, in the first embodiment, the heating unit 10 includes the heater 11 disposed inside the substrate stage ST so as to heat the substrate W via the substrate stage ST. With the configuration, the heating unit 10 can be realized by a simple configuration.

Note that the coating process unit 30 of the substrate processing apparatus 100 may supply an organic solvent containing a component for forming a self-assembled monolayer (SAM) onto the surface of the substrate W as the organic solvent. In the case in a step illustrated in, for example, FIG. 3C, organic molecules in the component in the organic solvent form single molecule layers while being spontaneously oriented each other. More specifically, the respective organic molecules have a functional group (adsorption group) having a high chemical affinity to the oxide film OXF1 and a functional group (orienting group) having a low chemical affinity to the oxide film OXF1, and the adsorption group is coupled with the oxide film OXF1 as well as the orienting group is oriented so as to face a side opposite to the oxide film OXF1. As a result, the organic film ORF which covers the oxide film OXF1 is configured such that, for example, respective molecules are oriented substantially uniformly as well as one molecule layer has an substantially uniform film thickness (for example, about 1 to 2 nm).

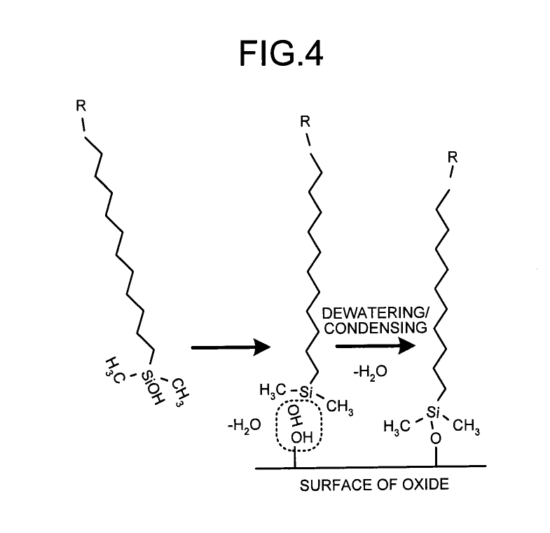

For example, as the component for forming the self-assembled monolayer, a component which applies an ultra water-repellent property (in which a contact angle of the component with water becomes, for example, 150° or more) onto the surface of the substrate W, for example, alkylsilane and fluoroalkylsilane can be used. As the component, fluoroalkylsilane containing a fluoroalkyl group (R) and a hydroxy group (—OH) can be used, and, for example, heptadecafluorotetra hydrodecyl triethoxysilane, heptadecafluorotetra hydrodecyl trichlorosilane, tridecafluorotetra hydrooctyl trichlorosilane, and the like can be used. In the case, at the step illustrated in FIG. 3C, as illustrated in, for example, FIG. 4, since a hydroxy group (—OH) in a component of the organic solvent causes a dewatering/condensing reaction between it as an adsorption group and a hydroxy group (—OH) in the oxide film OXF1, the organic film ORF is formed as the self-assembled monolayer for covering a surface of the oxide film OXF1. At the time, the alkyl group or the fluoroalkyl group (R) is exposed to the side opposite to the oxide film OXF1 and a surface of the organic film ORF is placed in such a state that the surface has, for example, an ultra water-repellent property by the alkyl group or the fluoroalkyl group (R) as well as has a low surface energy. That is, the surface of the substrate W is reformed.

Otherwise, the oxidation process unit 20 of the substrate processing apparatus 100 may be configured such that the diffusion plate 21 and the diffusion chamber CH3 are omitted.

Otherwise, as illustrated in FIG. 5, a film forming system 300i may include plural CVD devices 200i1, 200i2. In the case, the load lock chamber LD1 is disposed adjacent to the plural CVD devices 200i1, 200i2 and the substrate processing apparatus 100. A device AP1 illustrated in FIG. 5 is a device for performing a process before the film forming system 300i performs a process. Substrates subjected to the process by the apparatus AP1 are sequentially transported to the film forming system 300i by the carrying mechanism CM via a load lock chamber LD2.

For example, a case where substrates W1, W2, W3 are sequentially transported to the film forming system 300i will be examined. In the case, the substrate W1 is carried into the substrate processing apparatus 100 via the load lock chamber LD1, and after the substrate W1 is subjected to the preprocess by the substrate processing apparatus 100, it is carried into the CVD device 2001 via the load lock chamber LD1. During a period in which the substrate W1 is subjected to the film forming process by the CVD device 200i1, the substrate W2 is carried into the substrate processing apparatus 100 via the load lock chamber LD1, and after the substrate W2 is subjected to the preprocess by the substrate processing apparatus 100, it is carried into the CVD device 200i2 via the load lock chamber LD1. On the other hand, after the completion of the film forming process performed to the substrate W1 by the CVD device 200i1 during a period in which the substrate W2 is subjected to the film forming process by the CVD device 200i2, the substrate W1 is carried out by the carrying mechanism CM via the load lock chamber LD1. Further, during a period in which the substrate W2 is subjected to the film forming process by the CVD device 200i2, the substrate W3 is carried into the substrate processing apparatus 100 via the load lock chamber LD1 before or after the substrate W1 is carried out.

As described above, in the film forming system 300i, the preprocess by the substrate processing apparatus 100 and the film forming processes by the CVD devices 200i1, 200i2 can be performed to the plural substrates W1-W3 in parallel, respectively. As a result, the throughput of the processes performed to the plural substrates W1-W3 by the film forming system 300i can be improved as a whole.

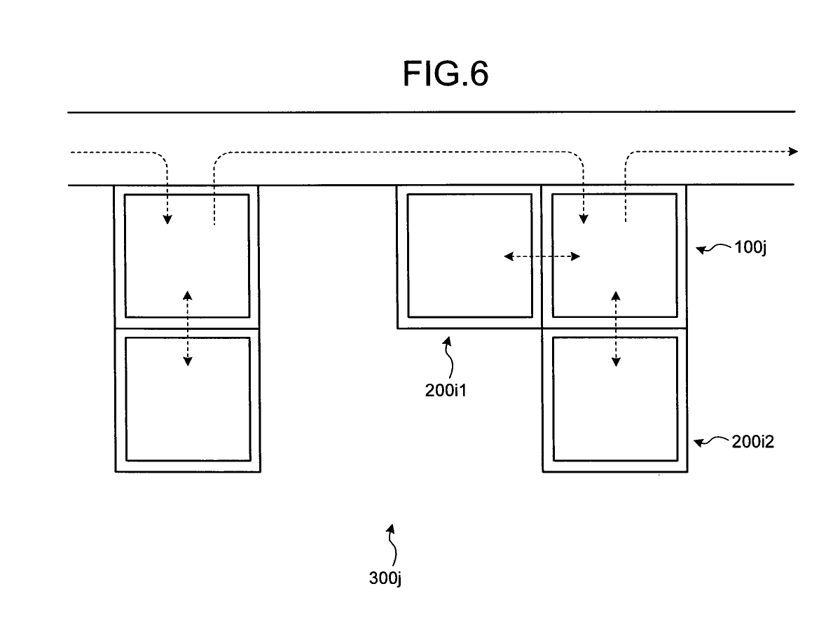

Otherwise, as illustrated in FIG. 6, a film forming system 300j may be configured such that the load lock chamber LD1 is omitted. In the case, a substrate processing apparatus 100j is disposed adjacent to the plural CVD devices 200i1, 200i2 and functions as a load lock chamber for sequentially transporting substrates to the plural CVD devices 200i1, 200i2 without exposing the substrates to the atmosphere.

For example, a case that the substrate W1, W2, W3 are sequentially transported to the film forming system 300j likewise the above case will be examined. In the case, the substrate W1 is directly carried into the substrate processing apparatus 100j without via the load lock chamber LD1 and is carried into the CVD device 200i1 without via the load lock chamber LD1 even after it is subjected to the preprocess by the substrate processing apparatus 100j. This is similar to the substrates W2, W3.

As described above, in the film forming system 300j, the plural substrates W1-W3 can be carried into and carried out from the substrate processing apparatus 100j and the CVD devices 200i1, 200i2 without via the load lock chamber LD1 in addition to that the preprocess by the substrate processing apparatus 100j and the film forming processes by the CVD devices 200i1, 200i can be carried out in parallel, respectively to the plural substrates W1-W3. As a result, the throughput of the processes performed to the plural substrates W1-W3 by the film forming system 300j can be more improved as a whole.

### SECOND EMBODIMENT

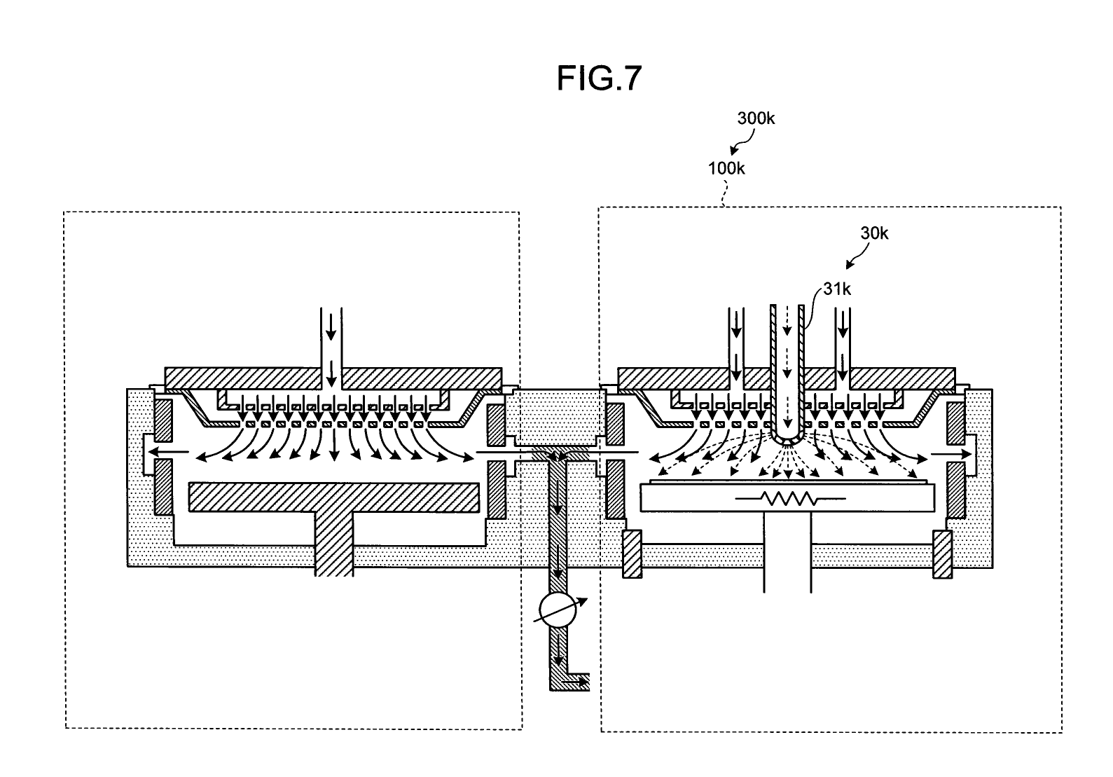

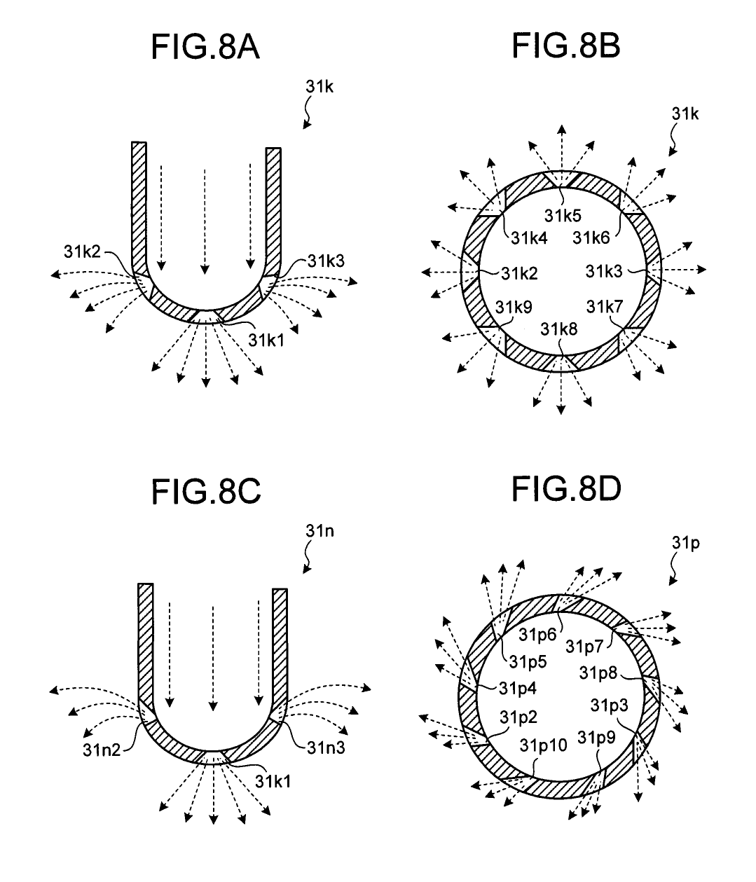

Next, a film forming system 300k according to a second embodiment will be explained using FIG. 7 and FIGS. 8A to 8D. FIG. 7 is a view illustrating a configuration of the film forming system 300k according to the second embodiment. FIGS. 8A to 8D are views illustrating a configuration of a spray nozzle in the second embodiment. Portions different from the first embodiment will be mainly described below.

The film forming system 300k includes a coating process unit 30k. The coating process unit 30k coats a surface of a substrate W with an organic solvent without rotating a substrate stage ST. Specifically, the coating process unit 30k does not include a rotation unit 32 (refer to FIG. 1) and includes a spray nozzle 31k. The spray nozzle 31k is disposed above the substrate stage ST and includes ejection ports 31k2-31k9 facing a peripheral portion of the substrate stage ST (refer to FIG. 8A and FIG. 8B) in addition to an ejection port 31k1 facing a central portion of the substrate stage ST. With the configuration, as illustrated by the broken arrows in FIG. 7, the spray nozzle 31k sprays the organic solvent onto the surface of the substrate W held by the substrate stage ST.

Specifically, as illustrated by FIG. 8A and FIG. 8B, the outer opening width of the respective ejection ports 31k1-31k9 in the spray nozzle 31k is made larger than the inner opening width thereof. With the configuration, as illustrated by broken arrows in FIG. 8A and FIG. 8B, the organic solvent can be sprayed onto the entire surface of the substrate W. That is, the organic solvent sprayed from the ejection port 31k1 is mainly directed to the central portion of the surface of the substrate W as well as the organic solvent sprayed from the ejection ports 31k2-31k9 is mainly directed to the peripheral portion of the surface of the substrate W.

As described above, in the second embodiment, since the spray nozzle 31k sprays the organic solvent onto the entire surface of the substrate W, the surface of the substrate W can be coated with the organic solvent without rotating the substrate stage ST.

Note that a spray nozzle 31n illustrated in FIG. 8C may be used in place of the spray nozzle 31k. In the spray the nozzle 31n, the center axes of ejection ports 31n2, 31n3 facing the peripheral portion of the substrate stage ST tilt upward with respect to the normal of a wall surface of the spray the nozzle 31n. With the configuration, the organic solvent sprayed from ejection ports 31n2, 31n3 can be more efficiently mainly directed to the peripheral portion of the surface of the substrate W.

Otherwise, a spray nozzle 31p illustrated in FIG. 8D may be used in place of the spray nozzle 31k. In the spray the nozzle 31p, the center axes of ejection ports 31p2-31p10 facing the peripheral portion of the substrate stage ST tilt in the circular cross section of the spray the nozzle 31p with respect to the radial direction in the circular cross section (at, for example, a uniform tilt angle). With the configuration, the organic solvent sprayed from the ejection ports 31n2, 31n3 can be more uniformly directed to the peripheral portion of the surface of the substrate W while forming a swirling flow.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate processing apparatus which performs a preprocess of a substrate to which a film forming process is performed by a CVD device, comprising:
a substrate process chamber in which a substrate stage is disposed, the substrate stage holding the substrate;
a heating unit which heats the substrate in the substrate process chamber via the substrate stage;
an oxidation process unit which oxidizes a surface of the substrate heated by the heating unit in the substrate process chamber; and
a coating process unit which coats the surface of the substrate oxidized by the oxidation process unit with an organic solvent in the substrate process chamber.

2. The substrate processing apparatus according to claim 1, wherein
the substrate has, on a surface, a groove or a hole into which an insulator is to be buried by the CVD device;
the heating unit heats the substrate so as to remove moisture on the surface of the substrate;
the oxidation process unit oxidizes the surface of the substrate from which the moisture is removed by the heating unit; and
the coating process unit coats the surface of the substrate oxidized by the oxidation process unit with an organic solvent.

3. The substrate processing apparatus according to claim 1, wherein
the coating process unit includes:
a rotation unit which rotates the substrate stage; and
a nozzle disposed above the substrate stage so as to supply the organic solvent onto the surface of the substrate.

4. The substrate processing apparatus according to claim 2, wherein
the coating process unit includes:
a rotation unit which rotates the substrate stage; and
a nozzle disposed above the substrate stage so as to supply the organic solvent onto the surface of the substrate.

5. The substrate processing apparatus according to claim 1, wherein
the coating process unit includes a spray nozzle disposed above the substrate stage so as to spray the organic solvent onto the surface of the substrate.

6. The substrate processing apparatus according to claim 2, wherein the coating process unit includes a spray nozzle disposed above the substrate stage so as to spray the organic solvent onto the surface of the substrate.

7. The substrate processing apparatus according to claim 1, wherein
the oxidation process unit includes:
a gas introducing chamber into which an oxidizing gas is introduced; and
a shower plate which isolates the gas introducing chamber from the substrate process chamber, the shower plate having a plurality of through holes, each of the plurality of through holes communicating the gas introducing chamber with the substrate process chamber,
wherein the oxidation process unit supplies the oxidizing gas from the gas introducing chamber onto the surface of the substrate in the substrate process chamber via the plurality of through holes.

8. The substrate processing apparatus according to claim 2, wherein
the oxidation process unit includes:
a gas introducing chamber into which an oxidizing gas is introduced; and
a shower plate which isolates the gas introducing chamber from the substrate process chamber, the shower plate having a plurality of through holes, each of the plurality of through holes communicating the gas introducing chamber with the substrate process chamber,
wherein the oxidation process unit supplies the oxidizing gas from the gas introducing chamber onto the surface of the substrate in the substrate process chamber via the plurality of through holes.

9. The substrate processing apparatus according to claim 1, wherein
the heating unit includes a heater disposed inside the substrate stage so as to heat the substrate via the substrate stage.

10. The substrate processing apparatus according to claim 2, wherein
the heating unit includes a heater disposed inside the substrate stage so as to heat the substrate via the substrate stage.

11. The substrate processing apparatus according to claim 1, wherein
the coating process unit coats the surface of the substrate with the organic solvent so as to form a self-assembled monolayer on the surface of the substrate.

12. The substrate processing apparatus according to claim 2, wherein
the coating process unit coats the surface of the substrate with the organic solvent so as to form a self-assembled monolayer on the surface of the substrate.

13. The substrate processing apparatus according to claim 3, wherein
the coating process unit coats the surface of the substrate with the organic solvent so as to form a self-assembled monolayer on the surface of the substrate.

14. The substrate processing apparatus according to claim 5, wherein
the coating process unit coats the surface of the substrate with the organic solvent so as to form a self-assembled monolayer on the surface of the substrate.

15. A film forming system comprising:
the substrate processing apparatus according to claim 1; and
a CVD device comprising a process chamber into which a substrate subjected to a preprocess by the substrate processing apparatus is carried without being exposed to an atmosphere, the CVD device performing a film forming process to the substrate in the process chamber.

16. A film forming system comprising:
the substrate processing apparatus according to claim 2; and
a CVD device comprising a process chamber into which a substrate subjected to a preprocess by the substrate processing apparatus is carried without being exposed to an atmosphere, the CVD device performing a film forming process to the substrate in the process chamber.

17. The film forming system according to claim 15 wherein
the film forming system comprises a plurality of the CVD devices, and
the substrate process chamber in the substrate processing apparatus functions as a load lock chamber which sequentially transports a plurality of the substrate to the plurality of the CVD devices without exposing the substrate to the atmosphere.

18. The film forming system according to claim 16 wherein
the film forming system comprises a plurality of the CVD devices, and
the substrate process chamber in the substrate processing apparatus functions as a load lock chamber which sequentially transports a plurality of the substrate to the plurality of the CVD devices without exposing the substrate to the atmosphere.

19. The film forming system according to claim 15 wherein
the film forming system comprises a plurality of the CVD devices, and
the film forming system further comprises a load lock chamber which sequentially transports a plurality of the substrate to the plurality of the CVD devices without exposing the substrate to the atmosphere.

20. The film forming system according to claim 16 wherein
the film forming system comprises a plurality of the CVD devices, and
the film forming system further comprises a load lock chamber which sequentially transports a plurality of the substrate to the plurality of the CVD devices without exposing the substrate to the atmosphere.
